(19) United States
(12) Patent Application Publication
(10) Pub. No.: US 2023/0064817 A1
(43) Pub. Date: Mar. 2, 2023

(54) PLASMA PROCESSING APPARATUS

(71) Applicant: Tokyo Electron Limited, Minato-ku, Tokyo (JP)

(72) Inventors: Taro IKEDA, Nirasaki-shi, Yamanashi (JP); Toshifumi KITAHARA, Fuchu-shi, Tokyo (JP)

(21) Appl. No.: 17/904,427

(22) PCT Filed: Feb. 15, 2021
(86) PCT No.: PCT/JP2021/005550

§ 371 Date: Aug. 17, 2022

(30) Foreign Application Priority Data
Feb. 26, 2020 (JP) 2020-030327

(51) Int. Cl. H01J 37/32

(52) U.S. Cl. CPC H01J 37/3244; H01J 37/32834; H01J 2237/327; H01J 37/32082

(57) ABSTRACT

A plasma processing apparatus, which introduces electromagnetic waves having a frequency of the VHF band or higher into a processing container and processes a substrate by using plasma generated from a gas, includes: a stage which is provided inside the processing container and on which the substrate is placed; an electromagnetic wave introducer formed to face an inner wall of the processing container and configured to introduce the electromagnetic waves into the processing container; and a dielectric member provided on the inner wall through which the electromagnetic waves propagate, wherein a first portion of the dielectric member protrudes from the inner wall toward the stage, and wherein a second portion of the dielectric member is inserted into a recess or step portion of the inner wall.

### TECHNICAL FIELD

The present disclosure relates to a plasma processing apparatus.

### BACKGROUND

A plasma processing apparatus capable of preventing an abnormal discharge from occurring between a stage and plasma has been proposed. For example, Patent Document 1 discloses a plasma processing apparatus which includes an upper electrode provided in a chamber to face a stage, a processing gas supply mechanism configured to supply a processing gas into the chamber, an exhaust mechanism configured to evacuate an interior of the chamber, and a power supply configured to supply radio-frequency power to the stage to form plasma of the processing gas in a processing space between the stage and the upper electrode. Patent Document 1 proposes providing a member that surrounds a side surface of a substrate on the stage to shield a short-circuit path from the plasma to the side surface of the stage.

### PRIOR ART DOCUMENT

[Patent Document]
Patent Document 1: Japanese laid-open publication No. 2003-100722

### SUMMARY

The present disclosure provides a plasma processing apparatus capable of preventing an abnormal discharge caused by electromagnetic waves having a frequency of the VHF band or higher.

An aspect of the present disclosure provides a plasma processing apparatus that introduces electromagnetic waves having a frequency of the VHF band or higher into a processing container and processes a substrate by using plasma generated from a gas, the plasma processing apparatus including: a stage which is provided inside the processing container and on which the substrate is placed; an electromagnetic wave introducer formed to face an inner wall of the processing container and configured to introduce the electromagnetic waves into the processing container; and a dielectric member provided on the inner wall through which the electromagnetic waves propagate, wherein a first portion of the dielectric member protrudes from the inner wall toward the stage, and wherein a second portion of the dielectric member is inserted into a recess or step portion of the inner wall.

According to an aspect, it is possible to prevent an abnormal discharge caused by electromagnetic waves having a frequency of the VHF band or higher.

### BRIEF DESCRIPTION OF DRAWINGS

FIG. 1 is a schematic cross-sectional view illustrating an example of a plasma processing apparatus according to an embodiment.

FIG. 2A is a view illustrating an example of a configuration and effect of a dielectric member according to a comparative example.

FIG. 2B is a view illustrating an example of a configuration and effect of a dielectric member according to the embodiment.

FIG. 3A is a view illustrating an example of the configuration and effect of a dielectric member according to comparative example.

FIG. 3B is a view illustrating the configuration and effect of the dielectric member according to the embodiment.

FIG. 4A is a view illustrating another example of the dielectric member according to the embodiment.

FIG. 4B is a view illustrating another example of the dielectric member according to the comparative example.

FIG. 4C is a view illustrating another example of the dielectric member according to the comparative example.

### DETAILED DESCRIPTION

Hereinafter, embodiments of the present disclosure will be described with reference to the accompanying drawings. In each of the drawings, the same components may be denoted by the same reference numerals, and redundant descriptions thereof may be omitted.

### [Plasma Processing Apparatus]

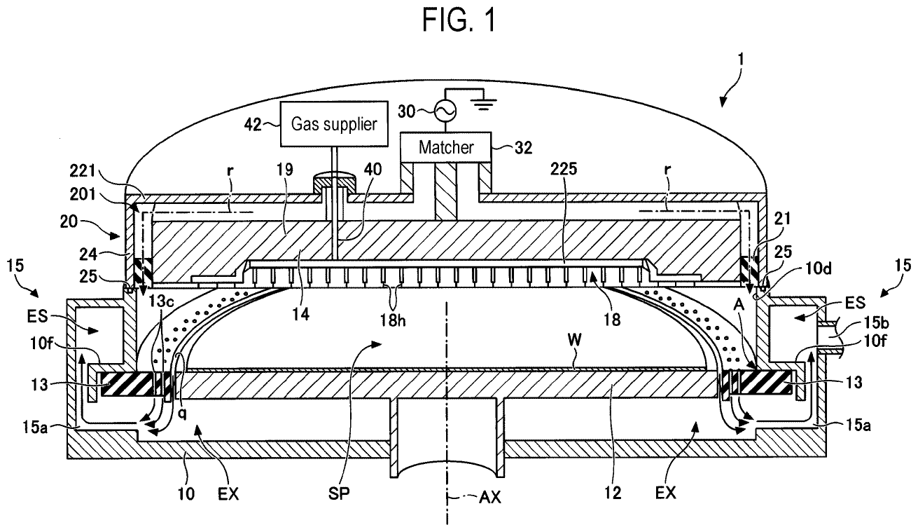

First, a plasma processing apparatus 1 according to an embodiment will be described with reference to FIG. 1. FIG. 1 is a schematic cross-sectional view illustrating the plasma processing apparatus 1 according to the embodiment. The plasma processing apparatus 1 illustrated in FIG. 1 includes a processing container 10, a stage 12, an upper electrode 14, and an electromagnetic wave introducer 20.

The processing container 10 has a substantially cylindrical shape and extends along a vertical direction. A central axis of the processing container 10 is an axis AX extending in the vertical direction. The processing container 10 is formed of a conductor such as aluminum or an aluminum alloy. A corrosion-resistant film is formed on a surface of the processing container 10. The corrosion-resistant film is formed of ceramic such as aluminum oxide or yttrium oxide. The processing container 10 is grounded.

The stage 12 is provided in the processing container 10. The stage 12 is configured to support a substrate W placed on a top surface thereof substantially horizontally. The stage 12 has a substantially disk-like shape. A central axis of the stage 12 substantially coincides with the axis AX.

The upper electrode 14 is provided above the stage 12 via a plasma processing space (hereinafter, referred to as a “processing space SP”) in the processing container 10. A central axis of the upper electrode 14 substantially coincides with the axis AX. The upper electrode 14 has a substantially disk-like shape. The upper electrode 14 includes a plate 18. The stage 12 and the plate 18 face each other.

The plate 18 is formed of a dielectric material such as ceramic and transmits electromagnetic waves having a frequency of the VHF band or higher. A bottom surface of the plate 18 is exposed to the processing space SP, and the electromagnetic waves transmitted through the plate 18 are radiated to the processing space SP. The upper electrode 14 further includes a base 19, which is provided above the plate 18. The base 19 may be formed of a metal such as aluminum. However, the base 19 is not limited to a metal, and may be formed of other materials.

A thickness of the plate 18 is thin at an outer peripheral portion thereof and thick at a central portion thereof. Thus, it possible to form uniform electric fields by electromagnetic waves in the processing space SP. By the electric fields of electromagnetic waves formed in the processing space SP, a gas in the processing space SP is excited, and plasma is generated from the gas. As a result, the plasma is generated with a uniform density distribution in the processing space SP. The substrate W on the stage 12 is subjected to a process such as film formation and etching, depending on chemical species from the plasma.

In addition, a corrosion-resistant film may be formed on at least the bottom surface of the plate 18. The corrosion-resistant film may include at least one of the group consisting of an yttrium oxide film, yttrium oxyfluoride, and yttrium fluoride. Other ceramic materials may also be used for the corrosion-resistant film.

A cylindrical member 24 surrounding the upper electrode 14 is provided above the processing container 10. The cylindrical member 24 has a substantially cylindrical shape and is formed of a conductor such as aluminum or an aluminum alloy. A central axis of the cylindrical member 24 substantially coincides with the axis AX. The cylindrical member 24 extends in the vertical direction. A lower end surface of the cylindrical member 24 is in contact with an upper end surface of the processing container 10. The processing container 10 is grounded. Therefore, the cylindrical member 24 is grounded. At an upper end of the cylindrical member 24, an upper wall portion 221 forming a waveguide passage r together with a top surface of the base 19 is located.

A seal 25 is interposed between a bottom surface of the cylindrical member 24 and an upper end surface of a main body of the processing container 10. The seal 25 has elasticity and is, for example, an O-ring made of rubber. The seal 25 extends circumferentially around the axis AX. In addition, a bottom surface of a waveguide 201 is not covered with an upper end surface of the main body of the processing container 10, but faces the processing space SP via a ring-shaped dielectric body 21 that isolates the waveguide 201 from the processing space SP. In the present specification, the cylindrical member 24 and the processing container 10 are distinguished, but the cylindrical member 24 is a portion of an inner wall of the processing container 10. A dielectric material may be embedded in all or a part of the waveguide 201.

With the configuration described above, the plasma processing apparatus 1 includes the electromagnetic wave introducer 20, which is formed to face the inner wall of the processing container 10 and introduces electromagnetic waves having a frequency of the VHF band or higher to the interior of the processing container 10. The electromagnetic wave introducer 20 includes the waveguide 201 that is bent at right angles from above the upper electrode 14 toward outside of a peripheral portion of the upper electrode 14. The electromagnetic wave introducer 20 propagates the electromagnetic waves of the VHF band to the waveguide passage r inside the waveguide 201, and introduces the electromagnetic waves into the processing space SP. The electromagnetic wave introducer 20 is not limited to the configuration as illustrated in FIG. 1 in which the electromagnetic waves are introduced downward from an end portion of the electromagnetic wave introducer 20, and may be configured to introduce electromagnetic waves inward from the end portion toward the center of the processing space SP in a plan view.

The electromagnetic waves have a frequency of the VHF band or higher, specifically 100 MHz or higher, and more specifically 150 MHz or higher. The electromagnetic waves are not limited to the electromagnetic waves of the VHF band, and may be electromagnetic waves of the microwave band. However, the electromagnetic waves of the microwave band in the present specification include electromagnetic waves having a frequency up to an upper limit of 3 GHz.

A power supply 30 is electrically connected to a top surface of the upper electrode 14 constituting an inner wall of the electromagnetic wave introducer 20 via a matcher 32. The power supply 30 is a power supply that generates electromagnetic waves. The power supply 30 may generate VHF waves or microwaves. The matcher 32 includes a matching circuit configured to match a load-side impedance seen from the power supply 30 with an output impedance of the power supply 30.

A gas diffusion space 225 is defined between a bottom surface of the base 19 and the plate 18. A pipe 40 is connected to the space 225. A gas supplier 42 is connected to the pipe 40. The gas supplier 42 includes one or more gas sources used for processing the substrate W. In addition, the gas supplier 42 includes one or more flow controllers configured to control flow rates of gases from the one or more gas sources, respectively.

The pipe 40 extends to the space 225. Since the waveguide 201 provided by the electromagnetic wave introducer 20 is made of a grounded conductor and the pipe 40 is also grounded, a gas is suppressed from being excited in the pipe 40. The gas supplied to the space 225 is ejected into the processing space SP via a plurality of gas ejection holes 18h of the plate 18. The electromagnetic waves propagate from the power supply 30 toward an outer periphery of the plate 18 via the waveguide 201 of the electromagnetic wave introducer 20, pass through the plate 18, and are supplied to the processing space SP from the bottom surface of the plate 18. The electromagnetic waves also propagate along an inner wall 10d of the processing container 10 via the waveguide 201 and are supplied to the processing space SP. The gas supplied to the processing space SP is turned into plasma by electric fields of the electromagnetic waves introduced into the processing space SP from the waveguide 201. The plasma processing apparatus 1 processes the substrate W with the generated plasma.

A dielectric member 13 is provided on the inner wall 10d (side wall) of the processing container 10 at a position substantially horizontal to the stage 12 to surround the stage 12. The dielectric member 13 is a substantially annular plate-shaped member. The dielectric member 13 is formed of, for example, a dielectric such as aluminum oxide (Al₂O₃) or quartz. The dielectric member 13 is configured to protrude from the inner wall 10d toward the stage 12 so as to reflect surface waves (travelling waves) of the electromagnetic waves introduced from the electromagnetic wave introducer 20 and propagating along the inner wall 10d. A step portion 10f is formed on the inner wall 10d, along which the electromagnetic waves propagate, at substantially the same height as the stage 12.

The dielectric member 13 is configured to be inserted along a bottom surface of the inner wall 10d (the step portion 10f) of the processing container 10, which is bent outward at right angles at a position A. A bottom surface of the dielectric member 13 is open to free space.

In the dielectric member 13, a plurality of exhaust holes 13c is formed to penetrate the dielectric member 13 in a thickness direction. The plurality of exhaust holes 13c is disposed at equal intervals in a circumferential direction of the dielectric member 13. A space between the dielectric member 13 and the stage 12 is an exhaust path q. The gas supplied to the processing space SP is transferred to an exhaust space EX below the stage 12 via the plurality of exhaust holes 13c and the exhaust path q. The exhaust space EX is in communication with an exhaust passage 15a in an exhaust mechanism 15 formed adjacent to an outer side wall of the processing container 10. The gas transferred to the exhaust space EX flows toward an outer periphery of the exhaust space EX, and then is transferred to an exhaust path ES, which is formed in the exhaust mechanism 15 above the exhaust passage 15a, via the exhaust passage 15a. The exhaust path ES is defined by the side wall of the processing container 10 and a wall of the exhaust mechanism 15, and is formed in an annular shape.

An exhaust device is connected to an exhaust port 15b formed in the exhaust path ES. The exhaust device includes a pressure control valve and a vacuum pump such as a turbo molecular pump and/or a dry pump. The exhaust device exhausts the gas in the processing container 10.

With the configuration described above, the gas in the processing container 10 is exhausted downward to the exhaust space EX, and further exhausted from the exhaust space EX to the exhaust path ES formed outside the side wall of the processing container 10. As a result, the plasma processing apparatus 1 can be reduced in size by exhausting the gas laterally while suppressing occurrence of an abnormal discharge in the exhaust path. In particular, in the plasma processing apparatus 1 in which a plurality of (e.g., two, four, or the like) stages illustrated in FIG. 1 are disposed and a plurality of substrates W can be processed at the same time, there is a great merit of having the exhaust mechanism 15 that exhausts the gas laterally. In this case, the apparatus can be made smaller and the footprint can be improved compared with a case in which a gas is exhausted downward of the processing container 10. However, the gas may be exhausted downward from the exhaust space EX by providing an exhaust port on the bottom wall of the processing container 10.

The stage 12 has a conductive layer for an electrostatic chuck and a conductive layer for a heater, which are not illustrated. The stage 12 may be a conductor such as aluminum for functioning as a lower electrode, but as an example, the stage is formed of an insulator such as aluminum nitride. The stage 12 has a substantially disk-like shape. The conductive layer of the stage 12 is made of a conductive material such as tungsten. The conductive layer is provided in the main body. When a DC voltage from a DC power supply is applied to the conductive layer for the electrostatic chuck, an electrostatic attractive force is generated between the stage 12 and the substrate W. Due to the generated electrostatic attractive force, the substrate W is attracted to and held by the stage 12. In another embodiment, the conductive layer may be a radio-frequency electrode. In this case, a power supply is electrically connected to the conductive layer via a matcher. In yet another embodiment, the conductive layer may be an electrode that is grounded. The conductive layer embedded in such an insulator may also function as a lower electrode for forming an electric field with the upper electrode.

### [Dielectric Member]

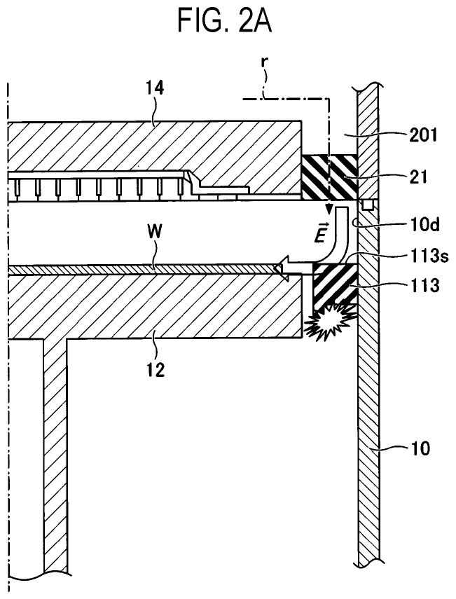

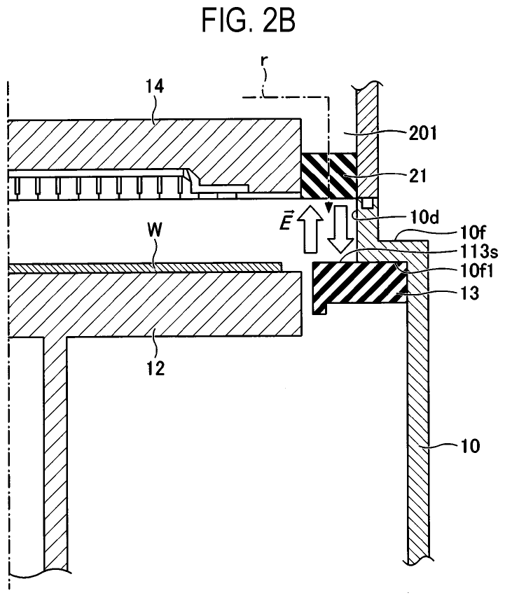

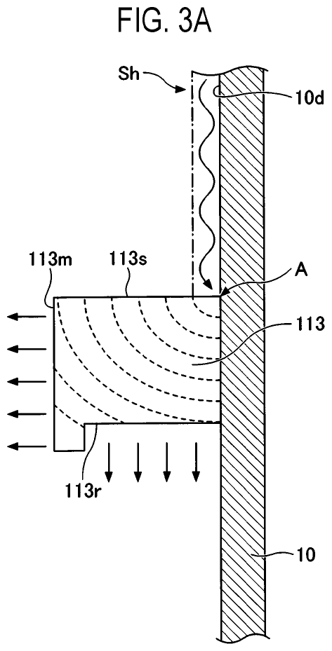

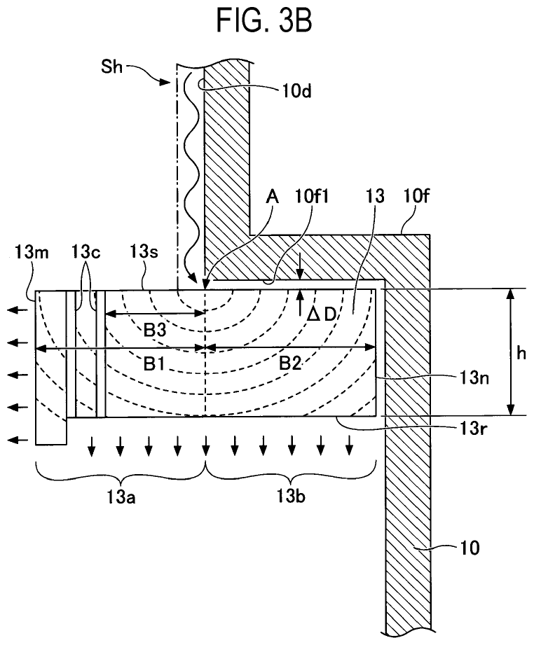

Next, the dielectric member 13 according to an embodiment will be described in detail with reference to FIGS. 2A, 2B, 3A, and 3B.

FIGS. 2A and 3A illustrate a dielectric member 113 according to a comparative example, and FIGS. 2B and 3B illustrate the dielectric member 13 according to the embodiment. The dielectric member 113 according to the comparative example of FIG. 2A is attached along the inner wall 10d of the processing container 10 so as to face the stage 12 in a direction substantially perpendicular to the inner wall 10d. In such a structure, electromagnetic waves propagating from the waveguide passage r of the waveguide 201 along the inner wall 10d are reflected by a top surface 113s of the dielectric member 113. Since the top surface 113s of the dielectric member 113 is a boundary between a vacuum space of the processing space SP and the dielectric member 113, which have different dielectric constants, the electric fields are strengthened in the top surface 113s. As a result, an abnormal discharge may occur between the stage 12 and the dielectric member 113.

For example, when radio-frequency waves having a frequency lower than the VHF band (30 M to 300 MHz) are introduced into the processing container 10, the radio-frequency waves do not have the property of surface waves propagating on the inner wall 10d, and are coupled between the stage 12 and the upper electrode 14 to generate discharge. Therefore, a phenomenon in which an abnormal discharge is generated between the stage 12 and the dielectric member 113 is unlikely to occur.

On the other hand, electromagnetic waves having a frequency band of VHF waves or microwaves are unlikely to be coupled between the stage 12 and the upper electrode 14, and surface waves of the electromagnetic waves propagate on the surface of the inner wall 10d of the processing container 10. Therefore, an abnormal discharge is likely to occur between the stage 12 and the dielectric member 113 due to the electromagnetic waves propagating along the inner wall 10d.

Therefore, in the plasma processing apparatus 1 according to the present embodiment, as illustrated in FIG. 2B, the dielectric member 13 has a discontinuous surface with respect to the surface of the inner wall 10d. The dielectric member 13 is disposed along the step portion 10f of the inner wall 10d of the processing container 10. That is, a part of the dielectric member 13 protrudes from the inner wall 10d toward the stage, and the other part thereof is inserted into the step portion 10f of the inner wall of the processing container 10 through which electromagnetic waves propagate. In the example of FIG. 2B, the other part of the dielectric member 13 is inserted along an inner surface 10f1 of the step portion 10f of the inner wall 10d.

Next, an operation of the dielectric member 13 configured as described above will be described while comparing with the dielectric member 113 according to the comparative example illustrated in FIG. 3A. As illustrated in FIGS. 3A and 3B, the surface waves of electromagnetic waves propagate in a sheath Sh formed on the inner wall 10d of the processing container 10. At this time, while emitting energy in the processing space SP, the surface waves of electromagnetic waves reach the dielectric member 113 disposed in the propagation path of the electromagnetic waves in the case of the comparative example, and reach the dielectric member 13 in the case of the present embodiment. The reached electromagnetic waves are reflected at the top surface 113s of the dielectric member 113 and the top surface 13s of the dielectric member 13, and parts of the electromagnetic waves are transmitted through the inside of the dielectric member 113 and the dielectric member 13.

Since a dielectric constant of the vacuum of the processing space SP is different from a dielectric constant of the dielectric member 113 and a dielectric constant of the dielectric member 13, electric fields of the electromagnetic waves are strengthened on the top surface 113s of the dielectric member 113 and the top surface 13s of the dielectric member 13. For example, when a metallic member is disposed instead of the dielectric member 113 and the dielectric member 13, the electric fields of electromagnetic waves become further stronger on a top surface of the metallic member than in the case of the dielectric members, and an abnormality discharge occurs at a boundary between the processing space SP and the metallic member. In contrast, in the case where the dielectric member 113 or the dielectric member 13 are disposed, the electric fields at the boundary with the processing space SP do not become stronger than those in the case where the metallic member is disposed.

As schematically indicated by the dotted lines in FIGS. 3A and 3B, in the dielectric member 113 and the dielectric member 13, electric field strengths of the electromagnetic waves transmitted through the inside of the dielectric member 113 and the dielectric member 13 are weakened downward in an arc shape centered on the position A.

In the arrangement of the dielectric member 113 in FIG. 3A, the electric fields of electromagnetic waves inside the dielectric member 113 are weakened while spreading leftward and downward from the position A. On the other hand, the electromagnetic waves spreading rightward from the position A are reflected by the inner wall 10d. As a result, the electric fields of the electromagnetic waves spreading leftward and downward from the position A have a certain degree of strength due to the electromagnetic waves propagating leftward from the position A and the electromagnetic waves that are reflected without propagating rightward from the position A. Thus, as illustrated in FIG. 3A, the electric fields leaking from a side surface 113m and a bottom surface 113r of the dielectric member 113 into the free space have a certain degree of strength as indicated by the arrows. As a result, as illustrated in FIGS. 2A and 3A, the electric fields are strengthened between the dielectric member 113 and the stage 12 or below the dielectric member 113, and an abnormal discharge may occur.

As described above, the abnormal discharge referred to in the present specification refers to an abnormal discharge occurring in the space between the stage and the dielectric member disposed on the inner wall 10d of the processing container 10, which is an electromagnetic wave propagation path, and the space below the dielectric member. In particular, in the electromagnetic waves having a frequency of the VHF band or higher, due to the property of surface waves propagating along the inner wall 10d of the processing container 10, an abnormal discharge is likely to occur in the space between the dielectric member and the stage and the space below the dielectric member, compared with radio-frequency waves having a frequency lower than the VHF band.

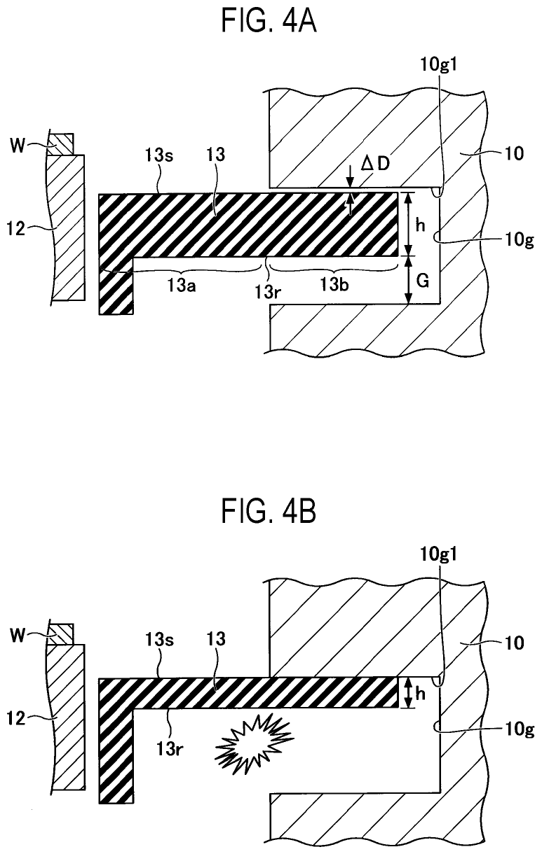

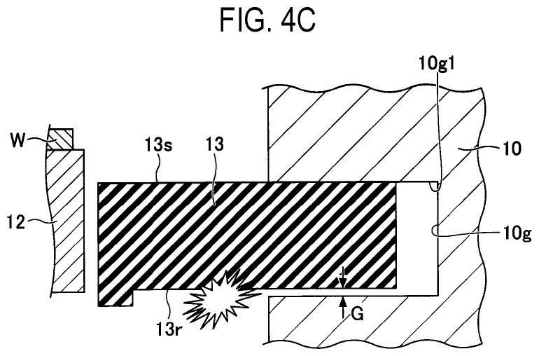

Therefore, the dielectric member 13 according to the present embodiment illustrated in FIG. 3B is configured to prevent an abnormal discharge in the vicinity of the stage 12 or the like when introducing electromagnetic waves having a frequency of the VHF band or higher into the plasma processing apparatus 1. Specifically, in the dielectric member 13 according to the present embodiment, a first portion 13a on a left-hand side from the position A of the inner wall 10d protrudes from the inner wall 10d toward the stage 12, and a second portion 13b on a right-hand side from the position A is inserted along the step portion 10f of the inner wall 10d. The second portion 13b of the dielectric member 13 may be inserted into a recess of the inner wall 10d through which the electromagnetic waves propagate (see a recess 10g in FIG. 4A).

It is desirable that the dielectric member 13 protrudes in a direction substantially perpendicular, that is, substantially 90 degrees, to the inner wall 10d of the processing container 10, which is a propagation path of the electromagnetic waves, toward the stage 12. However, the present disclosure is not limited thereto, and the dielectric member 13 may protrude while being inclined with respect to the inner wall 10d within a range of 90±30 degrees. This is to avoid the risk of occurrence of an abnormal discharge. When the dielectric member 13 is inclined with respect to the inner wall 10d beyond the range of 90±30 degrees, surface waves of the electromagnetic waves propagate toward an angle at which the surface waves easily propagate, and the risk of occurrence of an abnormal discharge increases.

The electric fields of electromagnetic waves are the strongest at the position A and are weakened downward from the position A while spreading leftward and rightward. As a result, the electric field strength is exponentially weakened while the electromagnetic waves propagating leftward in the first portion 13a and the electromagnetic waves propagating rightward in the second portion 13b pass through the inside of the dielectric member 13. Thus, as illustrated in FIG. 3B, the electric fields leaking from an inner side surface 13m and a bottom surface 13r of the dielectric member 13 are weakened to the extent that a discharge does not occur as indicated by the arrows. As a result, as illustrated in FIGS. 2B and 3B, most of the electromagnetic waves propagating along the inner wall 10d are reflected at the top surface 13s of the dielectric member 13, and the electromagnetic waves transmitted through the dielectric member 13 are weakened as described above. Thus, it is possible to prevent an abnormal discharge from occurring in the space between the dielectric member 13 and the stage 12 or below the dielectric member 13.

### [Dimensions of Dielectric Member]

Next, dimensions of the dielectric member 13 desirable for preventing an abnormal discharge from occurring in the space between the dielectric member 13 and the stage 12 or below the dielectric member 13 will be described. When an effective wavelength of electromagnetic waves incident on the dielectric member 13 is λ₀, a wavelength λ_{sw} of surface waves (sheath waves) of the electromagnetic waves propagating in the sheath Sh is represented as follows.

$${λ}_{s w} = \frac{{λ}_{0}}{40} to \frac{{λ}_{0}}{20}$$

In addition, an effective wavelength λ_{g} of the electromagnetic waves in the dielectric member 13 is represented by Equation (1).

$${λ}_{g} = \frac{{λ}_{s w}}{\sqrt{{ε}_{r}}} \qquad Equation ( 1 )$$

where εᵣ is a relative permittivity.

It is desirable that the first portion 13a of the dielectric member 13 protrudes from the inner wall 10d by ½ or more of the effective wavelength λ_{g} of the electromagnetic waves in the dielectric member 13. That is, it is desirable that a radial width B1 from the inner wall 10d to the inner side surface 13m of the dielectric member 13, as illustrated in FIG. 3B, is ½ or more of the effective wavelength λ_{g} of the electromagnetic waves in the dielectric member 13. In addition, it is desirable that a width B1 is 5 mm or more.

The effective wavelength λ₀ of the VHF electromagnetic waves of 180 MHz is about 1,600 mm. At this time, the wavelength λ_{sw} of the surface waves of the electromagnetic waves is 40 mm to 80 mm. From Equation (1), the effective wavelength λ_{g} of the electromagnetic waves in the dielectric member 13 is 13 mm to 26 mm. From the above, it is more desirable that the width B1 of the dielectric member 13 is 6.5 mm or more.

It is desirable that the second portion 13b of the dielectric member 13 is inserted from the inner wall 10d along the inner surface 10f1 of the step portion 10f by ¼ or more of the effective wavelength) λ_{g} of the electromagnetic waves in the dielectric member 13. That is, it is desirable that the radial width B2 from the inner wall 10d to the outer side surface 13n of the dielectric member 13, as illustrated in FIG. 3B, is ¼ or more of the effective wavelength) λ_{g} of the electromagnetic waves in the dielectric member 13. In addition, it is desirable that the width B2 is, for example, 5 mm or more.

It is desirable that a thickness h of the dielectric member 13 is ½ or more of the effective wavelength) λ_{g} of the electromagnetic waves in the dielectric member 13. Furthermore, it is desirable that the thickness h of the dielectric member 13 is, for example, 5 mm or more.

It is desirable that a gap ΔD between the inner surface 10f1 of the step portion 10f of the inner wall 10d and the top surface 13s of the dielectric member 13 facing the inner surface 10f1 is 0.5 mm or less. Similarly, it is desirable that the gap ΔD between a top surface 10g1 of the recess 10g of the inner wall 10d illustrated in FIG. 4A and the top surface 13s of the dielectric member 13 facing the top surface 10g1 is 0.5 mm or less. With this configuration, it is possible to prevent plasma from being generated in the gap ΔD. With this configuration, it is possible to prevent an abnormal discharge from occurring on the top surface 13s of the dielectric member 13.

A plurality of exhaust holes 13c penetrating the dielectric member 13 in the thickness direction is formed in the first portion 13a of the dielectric member 13. The plurality of exhaust holes 13c is formed at locations distanced from the inner wall 10d in the radial direction by ¼ or more of the effective wavelength) λ_{g} of the electromagnetic waves in the dielectric member 13. That is, it is desirable that a distance B3 from the inner wall 10d to the exhaust holes 13c, as illustrated in FIG. 3B, is ¼ or more of the effective wavelength) λ_{g} of the electromagnetic waves in the dielectric member 13. It is desirable that the distance B3 is, for example, 5 mm or more. With this configuration, it is possible to prevent an abnormal discharge from occurring in the exhaust holes 13c. In addition, a diameter φ of the exhaust holes 13c may be 2 mm to 3 mm.

When the exhaust holes 13c are provided in the dielectric member 13 as described above, it is desirable to form the exhaust holes 13c at locations distanced from the position A which is a central portion where the electric fields are most concentrated. In addition, a convex portion extending downward from the inner side surface 13m of the dielectric member 13 is for securing an exhaust path and for preventing entry and adhesion of a reaction product into the exhaust space EX. However, there may be no convex portion extending downward from the inner side surface 13m of the dielectric member 13.

In such a configuration, the free space is partitioned by disposing the dielectric member 13 on the inner wall 10d of the processing container 10 through which the surface waves of electromagnetic waves propagate. Thus, it is possible to substantially reflect travelling waves of the electromagnetic waves by the dielectric member 13. Although a part of the electromagnetic waves is transmitted through the inside of the dielectric member 13, it is possible to prevent an abnormal discharge by exponentially attenuating the electric fields inside the dielectric member 13. As described above, weak electric fields that do not cause a discharge are emitted to the free space below the bottom surface 13r of the dielectric member 13.

However, when the space between the bottom surface 13r of the dielectric member 13 and the surface of the inner wall 10d facing the bottom surface 13r is narrow, an abnormal discharge may occur on the bottom surface 13r of the dielectric member 13. Therefore, the bottom surface 13r of the dielectric member 13 is exposed to an internal space of the processing container 10. In addition, it is desirable that a distance between the bottom surface 13r of the dielectric member 13 and the surface of the inner wall 10d of the processing container 10 facing the bottom surface 13r is 5 mm or more. For example, as illustrated in FIG. 4A, when the second portion 13b of the dielectric member 13 is inserted into the recess 10g of the inner wall 10d through which the electromagnetic waves propagates, it is desirable that a gap G between the bottom surface 13r of the dielectric member 13 and the surface of the inner wall 10d facing the bottom surface 13r is 5 mm or more. With this configuration, it is possible to prevent an abnormal discharge from occurring in the free space below the bottom surface 13r of the dielectric member 13. It is desirable that a horizontal depth of the recess 10g is 15 mm or more.

FIG. 4A is a configuration example of the dielectric member 13 according to the embodiment, and FIGS. 4B and 4C are comparative examples. FIGS. 4A to 4C are examples of simulation results. FIG. 4A illustrates an example in which the thickness h of the dielectric member 13 is 7 mm and the gap G is 5 mm. Since the dielectric member 13 is sufficiently thick, electric fields are sufficiently attenuated inside the dielectric member 13. Moreover, since the gap G between the bottom surface 13r of the dielectric member 13 and the surface of the inner wall 10d is sufficient, it is possible to prevent an abnormal discharge from occurring in the free space below the bottom surface 13r of the dielectric member 13.

FIG. 4B illustrates an example in which the thickness h of the dielectric member 13 is 2 mm. Since the thickness of the dielectric member 13 is insufficient, electric fields are insufficiently attenuated inside the dielectric member 13, and an abnormal discharge occurs in the free space below the bottom surface 13r of the dielectric member 13.

FIG. 4C illustrates an example in which the gap G between the bottom surface 13r of the dielectric member 13 and the surface of the inner wall 10d facing the bottom surface 13r is 1 mm. Since the gap G is insufficient, the electric field strength is increased on a metallic surface of the recess 10g facing the bottom surface 13r by the electric fields emitted to the free space below the bottom surface 13r of the dielectric member 13, and an abnormal discharge occurs.

As described above, with the plasma processing apparatus 1 according to the present embodiment, it is possible to prevent an abnormal discharge by providing the dielectric member 13 in the propagation path of electromagnetic waves having a frequency of the VHF band or higher.

It shall be understood that the plasma processing apparatus according to the embodiments disclosed herein are illustrative and not restrictive in all aspects. The above-described embodiments may be modified and improved in various forms without departing from the scope and spirit of the appended claims. The matters described in in the plurality of embodiments may take other configurations within a non-contradictory range, and may be combined within a non-contradictory range.

The plasma processing apparatus of the present disclosure is applicable to any type of apparatus such as a radial line slot antenna type apparatus, an electron cyclotron resonance plasma (ECR) type apparatus, or a helicon wave plasma (HWP) type apparatus.

The present international application claims priority based on Japanese Patent Application No. 2020-030327 filed on Feb. 26, 2020, the disclosure of which is incorporated herein in its entirety by reference.

### EXPLANATION OF REFERENCE NUMERALS

1: plasma processing apparatus, 10: processing container, 12: stage, 13: dielectric member, 13a: first portion of dielectric member, 13b: second portion of dielectric member, 13c: exhaust hole, 14: upper electrode, 15: exhaust mechanism, 18: plate, 18h: gas ejection hole, 20: electromagnetic wave introducer, 21: ring-shaped dielectric body, 30: power supply, 32: matcher, 40: pipe, 42: gas supplier, 201: dielectric path, r: waveguide passage, SP: processing space, EX: exhaust space, ES: exhaust path, W: substrate

1-15. (canceled)

16. A plasma processing apparatus that introduces electromagnetic waves having a frequency of the very high frequency (VHF) band or higher into a processing container and processes a substrate by using plasma generated from a gas, the plasma processing apparatus comprising:
a stage which is provided inside the processing container and on which the substrate is placed;
an electromagnetic wave introducer formed to face an inner wall of the processing container and configured to introduce the electromagnetic waves into the processing container; and
a dielectric member provided on the inner wall through which the electromagnetic waves propagate,
wherein a first portion of the dielectric member protrudes from the inner wall toward the stage, and
wherein a second portion of the dielectric member is inserted into a recess or step portion of the inner wall.

17. The plasma processing apparatus of claim 16, wherein the dielectric member is inclined with respect to the inner wall within a range of 90±30 degrees and protrudes toward the stage.

18. The plasma processing apparatus of claim 17, wherein the dielectric member protrudes radially from the inner wall by ½ or more of an effective wavelength λ_{g} of the electromagnetic waves in the dielectric member.

19. The plasma processing apparatus of claim 18, wherein the dielectric member has a thickness of ½ or more of the effective wavelength λ_{g} of the electromagnetic waves in the dielectric member.

20. The plasma processing apparatus of claim 19, wherein the dielectric member has a bottom surface exposed to an internal space of the processing container.

21. The plasma processing apparatus of claim 20, wherein a distance between the bottom surface of the dielectric member and a surface of the inner wall facing the bottom surface is 5 mm or more.

22. The plasma processing apparatus of claim 21, wherein a distance from a top surface of the second portion of the dielectric member and a surface of the inner wall facing the top surface is 0.5 mm or less.

23. The plasma processing apparatus of claim 22, wherein a plurality of exhaust holes penetrating the dielectric member in a thickness direction is formed in the first portion of the dielectric member.

24. The plasma processing apparatus of claim 23, wherein the plurality of exhaust holes is formed at locations distanced radially from the inner wall by ¼ or more of the effective wavelength λ_{g} of the electromagnetic waves in the dielectric member.

25. The plasma processing apparatus of claim 24, wherein the electromagnetic waves have a frequency of 100 MHz or higher.

26. The plasma processing apparatus of claim 25, wherein a space between the first portion of the dielectric member and the stage is a first exhaust path, and
wherein the plasma processing apparatus is configured such that the gas is exhausted from an exhaust space, which is in communication with the first exhaust path and is located below the dielectric member.

27. The plasma processing apparatus of claim 26, wherein the exhaust space below the dielectric member is in communication with a second exhaust path formed outside a side wall of the processing container, and
wherein the plasma processing apparatus is configured such that the gas is exhausted laterally from the second exhaust path via the exhaust space below the dielectric member.

28. The plasma processing apparatus of claim 23, wherein the plurality of exhaust holes is formed at locations distanced radially from the inner wall by 5 mm or more.

29. The plasma processing apparatus of claim 16, wherein the dielectric member protrudes radially from the inner wall by ½ or more of an effective wavelength λ_{g} of the electromagnetic waves in the dielectric member.

30. The plasma processing apparatus of claim 16, wherein the dielectric member protrudes radially from the inner wall by 5 mm or more.

31. The plasma processing apparatus of claim 16, wherein the dielectric member has a thickness of ½ or more of an effective wavelength λ_{g} of the electromagnetic waves in the dielectric member.

32. The plasma processing apparatus of claim 16, wherein the dielectric member has a thickness of 5 mm or more.

33. The plasma processing apparatus of claim 16, wherein the dielectric member has a bottom surface exposed to an internal space of the processing container.

34. The plasma processing apparatus of claim 16, wherein a distance from a top surface of the second portion of the dielectric member and a surface of the inner wall facing the top surface is 0.5 mm or less.

35. The plasma processing apparatus of claim 16, wherein a plurality of exhaust holes penetrating the dielectric member in a thickness direction is formed in the first portion of the dielectric member.
